(19) United States
(12) Patent Application Publication
(10) Pub. No.: US 2026/0202755 A1
(43) Pub. Date: Jul. 16, 2026

(54) ELECTROMAGNETIC FIELD CHARACTERISTIC SIMULATION METHOD AND ELECTROMAGNETIC FIELD CHARACTERISTIC SIMULATION SYSTEM

(71) Applicant: Samsung Electronics Co., Ltd., Suwon-si (KR)

(72) Inventors: Koji Murata, Yokohama (JP); Yunsu Jang, Suwon-si (KR); Yukihide Tsuji, Suwon-si (KR); Keita Suzuki, Yokohama (JP)

(21) Appl. No.: 19/447,147

(22) Filed: Jan. 13, 2026

(30) Foreign Application Priority Data
Jan. 14, 2025 (JP) 2025-005080
Aug. 18, 2025 (KR) 10-2025-0114427

(51) Int. Cl. G03F 7/00; G06F 17/13; G06F 17/16

(52) U.S. Cl. CPC G03F 7/705; G06F 17/13; G06F 17/16

(57) ABSTRACT

An electromagnetic field characteristic simulation method includes decomposing partially coherent light incident on an incident surface into one or more light components for each incident direction with respect to an incident surface, and performing an electromagnetic field analysis on each light component. The performing of the electromagnetic field analysis repeats determining whether or not a current light component is a light component firstly calculated by an electromagnetic field analysis calculation, obtaining a result of the electromagnetic field analysis calculation by executing an operation on the current light component according to a result of the determining, adding the result obtained in the obtaining to an accumulated result, and storing the accumulated result in a first storage area, and normalizing the result in response to the current light component that is firstly calculated, associating the normalized result to the same incident direction, and storing the normalized result in a second storage area.

### CROSS-REFERENCE TO RELATED APPLICATIONS

This application is based on and claims priority under 35 U.S.C. §119 to Japanese Patent Application No. 2025-005080, filed on January 14, 2025, in the Japan Patent Office, and Korean Patent Application No. 10-2025-0114427, filed on August 18, 2025, in the Korean Intellectual Property Office, the disclosures of each of which are incorporated by reference herein in their entirety.

### BACKGROUND

The disclosure relates to an electromagnetic field characteristic simulation method and an electromagnetic field characteristic simulation system, and more particularly, to a method and system for simulating the electromagnetic field characteristics of partially coherent light.

For example, light sources with diffusion used in photolithography, etc., are known to emit partially coherent light. In photolithography, light emitted from a light source propagates while interacting with an optical device and then enters a resist as partially coherent light. It is known that the behavior of light when partially coherent light is incident on a resist may be simulated using an electromagnetic field characteristic simulation method.

As the method of simulating electromagnetic field characteristics, an electromagnetic field simulation method is known, for example, by the finite difference time domain (FDTD) technique. The FDTD technique is one of techniques for solving Maxwell's equations. When calculating three-dimensional (3D) electromagnetic field analysis using this technique, calculation time thereof becomes very large.

A technique that can reduce the calculation time is desirable when analyzing electromagnetic field characteristics to simulate how light propagates within a resist in photolithography.

### PRIOR ART DOCUMENT

### PATENT DOCUMENT

Patent Document 1: Japanese Patent Application Laid-Open No. 2003-28581

### SUMMARY

The disclosure provides an electromagnetic field characteristic simulation method in which an electromagnetic field characteristic simulation is performed at high speed by reducing a calculation time required for the electromagnetic field characteristic simulation method when partially coherent light is incident on a three-dimensional structure.

According to an aspect of the present disclosure, an electromagnetic field characteristic simulation method, in which a computer uses an electromagnetic field analysis technique to simulate electromagnetic field characteristics of partially coherent light incident on a three-dimensional target structure, includes decomposing the partially coherent light incident on an incident surface of the three-dimensional target structure into one or more light components for each incident direction with respect to the incident surface of the three-dimensional target structure, and performing an electromagnetic field analysis on each of the one or more light components. The performing of the electromagnetic field analysis repeats operations of determining whether or not a current light component on which the electromagnetic field analysis is to be performed is a light component that is firstly calculated by an electromagnetic field analysis calculation among one or more light components with the same incident direction with respect to the incident surface, wherein the one or more light components with the same incident direction includes the current light component, obtaining a result of the electromagnetic field analysis calculation by executing an operation on the current light component according to a result of the determining, adding the result of the electromagnetic field analysis calculation obtained in the obtaining to an accumulated result, and storing the accumulated result in a first storage area, and normalizing the result of the electromagnetic field analysis calculation in response to the current light component being determined as the light component that is firstly calculated among the one or more light components with the same incident direction with respect to the incident surface, associating the normalized result to the same incident direction with respect to the incident surface, and storing the normalized result in a second storage area.

According to an aspect of the present disclosure, an electromagnetic field characteristic simulation system comprising a computing device and a memory device, and simulating electromagnetic field characteristics of partially coherent light incident on a three-dimensional target structure using an electromagnetic field analysis technique, wherein the memory device stores a program to be run in the computing device, the program causes the computing device to execute operations of decomposing the partially coherent light incident on an incident surface of the three-dimensional target structure into one or more light components for each incident direction with respect to the incident surface of the three-dimensional target structure, and performing an electromagnetic field analysis on each of the one or more light components. The performing of the electromagnetic field analysis repeats operations of determining whether or not a current light component on which the electromagnetic field analysis is to be performed is a light component that is firstly calculated by an electromagnetic field analysis calculation among one or more light components with the same incident direction with respect to the incident surface, wherein the one or more light components with the same incident direction includes the current light component, obtaining a result of the electromagnetic field analysis calculation by executing an operation on the current light component according to a result of the determining, adding the result of the electromagnetic field analysis calculation obtained in the obtaining, and storing the result in a first storage area, and normalizing the result of the electromagnetic field analysis calculation in response to the current light component being determined as the light component to be firstly calculated among the one or more light components with the same incident direction with respect to the incident surface, associating the normalized result to the incident direction with respect to the incident surface, and storing the normalized result in a second storage area.

According to an aspect of the present disclosure, an electromagnetic field characteristic simulation system includes a processor; and a memory that stores instructions executed by the processor. The processor is configured to, by executing the instructions, decompose partially coherent light incident on an incident surface of a resist into one or more light components for each incident direction with respect to the incident surface, perform an operation of an electromagnetic field analysis calculation to produce a first calculation result, for a first light component that is firstly calculated by the electromagnetic field analysis calculation among the one or more light components with the same incident direction with respect to the incident surface, normalize the first calculation result to generate a normalized result, and perform an operation of multiplying the normalized result by an amplitude of a second light component to produce a second calculation result, in which the second light component is not a light component that is firstly calculated by the electromagnetic field analysis calculation among the one or more light components with the same incident direction with respect to the incident surface.

### BRIEF DESCRIPTION OF THE DRAWINGS

Embodiments will be more clearly understood from the following detailed description taken in conjunction with the accompanying drawings in which:

FIG. 1 is a diagram explaining partially coherent light in photolithography;

FIG. 2 is a diagram explaining an electromagnetic field analysis technique in an electromagnetic field characteristic simulation system according to an embodiment;

FIG. 3 is a diagram illustrating an example configuration of an electromagnetic field characteristic simulation system according to an embodiment;

FIG. 4 is a functional block diagram illustrating an example of a computing device in an electromagnetic field characteristic simulation system, according to an embodiment;

FIG. 5 is a diagram illustrating a mesh space in a wavevector domain defined for a plurality of optical devices;

FIG. 6 is a diagram illustrating a state in which a width of a mesh in the mesh space of FIG. 5 is adjusted;

FIG. 7 is a diagram illustrating an example of processing flow of an electromagnetic field characteristic simulation method;

FIG. 8 is a diagram illustrating an example of processing flow of an electromagnetic field characteristic simulation method, according to a comparative example;

FIG. 9 is a diagram illustrating shapes of masks used as an example in the simulation of electromagnetic field characteristics in photolithography;

FIG. 10 is a diagram illustrating electromagnetic field characteristics simulated when the masks of FIG. 9 are used; and

FIG. 11 is a diagram illustrating the calculation time when an electromagnetic field characteristic simulation method according to an embodiment and an electromagnetic field characteristic simulation method according to a comparative example are executed.

### DETAILED DESCRIPTION OF THE EMBODIMENTS

Hereinafter, embodiments of the disclosure will be described in detail with reference to the attached drawings. In the drawings below, identical reference numerals indicate identical components, and repeated descriptions are omitted. In addition, the drawings is schematic, and the dimensional relationship of each component, the ratio of each element, etc. may differ from the actual ones, and the dimensional relationship or ratio between drawings may also differ from each other.

In an electromagnetic field characteristic simulation system of an embodiment, the electromagnetic field characteristics of partially coherent light incident on a three-dimensional target structure may be simulated using an electromagnetic field analysis technique. In an embodiment, as an example, a case of simulating the propagation of partially coherent light within a resist in photolithography will be described.

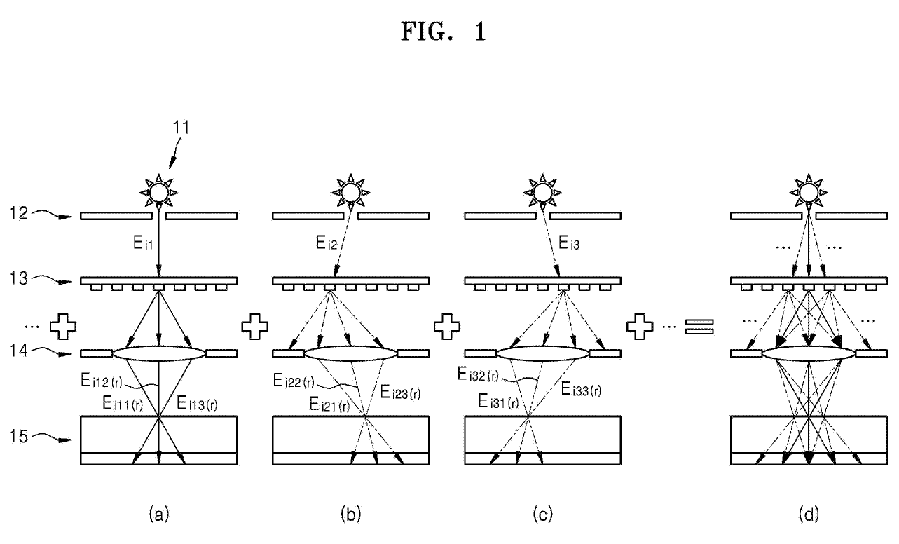

FIG. 1 is a diagram explaining partially coherent light in photolithography.

In photolithography, light emitted from a light source may propagate through optical elements such as a mask and a lens and then strikes a surface of a resist. In an example shown in FIG. 1, light emitted from a light source 11 through a slit 12 may pass through a mask 13 and a lens 14 until the light enters a resist 15. When the light is first emitted through the slit 12, the light emitted from the light source 11 may be diffused and propagated, and phase of the light may change depending on a direction from which the light is emitted. The components of light emitted in the same direction from the slit 12 may interfere with each other because the components have the same phase, but the components of light emitted in different directions do not interfere with each other because the components have different phases. That is, the light shown in FIG. 1 may be referred to as partially coherent light.

For the partially coherent light, it is necessary to calculate the interference for each of phase components and calculate the intensity of the propagating light. That is, as illustrated in FIG. 1, for the light incident on a surface of the resist 15, it is necessary to calculate a light component by calculating the interference for each of the phase components (a), (b), and (c) of the light emitted from the light source 11. The phase components (a), (b), and (c) may have different incidence directions emitted from the light source 11. Specifically, light Eᵢ₁ shown in (a) of FIG. 1 may pass through the lens 14 and be incident on the surface of the resist 15 as three light components Eᵢ₁₁₍ᵣ₎, Eᵢ₁₂₍ᵣ₎, and Eᵢ₁₃₍ᵣ₎ with different incident directions. Similarly, light Eᵢ₂ shown in (b) of FIG. 1 may pass through the lens 14 and be incident on the surface of the resist 15 as three light components Eᵢ₂₁₍ᵣ₎, Eᵢ₂₂₍ᵣ₎, and Eᵢ₂₃₍ᵣ₎ with different incident directions, and light Eᵢ₃ shown in (c) of FIG. 1 may pass through the lens 14 and be incident on the surface of the resist 15 as three light components Eᵢ₃₁₍ᵣ₎, Eᵢ₃₂₍ᵣ₎, and Eᵢ₃₃₍ᵣ₎ with different incident directions.

The behavior of partially coherent light that propagates through a three-dimensional target structure such as the resist 15 may be obtained through an electromagnetic field analysis technique. First, by performing electromagnetic field analysis calculations for each of light components Eᵢ₁₁₍ᵣ₎, Eᵢ₁₂₍ᵣ₎, Eᵢ₁₃₍ᵣ₎, Eᵢ₂₁₍ᵣ₎, Eᵢ₂₂₍ᵣ₎, Eᵢ₂₃₍ᵣ₎, Eᵢ₃₁₍ᵣ₎, Eᵢ₃₂₍ᵣ₎, and Eᵢ₃₃₍ᵣ₎ incident on the three-dimensional target structure in each incident direction, E₁₁₍ᵣ₎, E₁₂₍ᵣ₎, E₁₃₍ᵣ₎, E₂₁₍ᵣ₎, E₂₂₍ᵣ₎, E₂₃₍ᵣ₎, E₃₁₍ᵣ₎, E₃₂₍ᵣ₎, and E₃₃₍ᵣ₎ may be calculated. Afterwards, the square of the absolute value of the sum of the light components for each phase may be calculated for solutions to be obtained, and by adding them again, the final result of light intensity analysis may be calculated as the solution (I₍ᵣ₎=|E₁₁₍ᵣ₎ + E₁₂₍ᵣ₎ + E₁₃₍ᵣ₎|²+|E₂₁₍ᵣ₎ + E₂₂₍ᵣ₎ + E₂₃₍ᵣ₎|²+|E₃₁₍ᵣ₎ + E₃₂₍ᵣ₎ + E₃₃₍ᵣ₎|²). Here, “r” represents the specific spatial coordinate on the surface of the resist 15. For example, each light component may be associated with a specific incident direction, which is organized within a mesh space in a wavevector domain, which will be described later. All light components that strike the target surface from the exact same direction may be mapped to the same mesh. This allows the simulation to treat all components on that mesh as having the same electromagnetic field behavior (since Maxwell's equations are linear) and leverage the efficiency shortcut.

In an embodiment, the propagation of light when partially coherent light, as shown in FIG. 1, is incident on an incident surface of the resist 15, which is a three-dimensional target structure, may be simulated using the electromagnetic field analysis technique. In an embodiment, the incident partially coherent light may be decomposed into one or more light components for each incident direction with respect to the incident surface of the resist 15, which is the three-dimensional target structure. General known techniques may be used as a technique for decomposing light components.

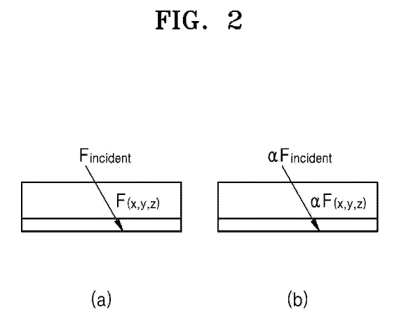

FIG. 2 is a diagram explaining an electromagnetic field analysis technique in an electromagnetic field characteristic simulation system according to an embodiment.

In the electromagnetic field characteristic simulation system according to an embodiment, the electromagnetic field analysis calculation may be performed by a technique for numerically analyzing Maxwell's equations, using light components decomposed into one or more for each incident direction with respect to the incident surface of the resist 15, which is the three-dimensional target structure. For example, the light components may be inputs of the Maxwell’s equations, and the output of the equations may be an intensity distribution generated by the light components within the resist 15.

The behavior of electromagnetic fields may be described as a solution to Maxwell's equations. Since Maxwell's equations are linear equations, when an electromagnetic field "F" in a target system is the solution thereof, the electromagnetic field "αF" which is an integer multiple of that may also be seen as the solution in the system thereof. For example, as shown in (a) of FIG. 2, an incident electromagnetic field F_{incident} may form a complex electromagnetic field distribution F(x, y, z) by multiple reflections within the three-dimensional structure. At this time, if it is known that the electromagnetic field distribution F(x, y, z) may be formed within the three-dimensional structure by the incident electromagnetic field F_{incident}, it may be said that the electromagnetic field distribution formed within the three-dimensional structure by the incident electromagnetic field αF_{incident} may be αF(x, y, z).

In the electromagnetic field analysis technique in the electromagnetic field characteristic simulation system according to an embodiment, the computational cost (e.g., time required for calculation, amount of calculation) may decrease by substituting part of the calculation or performing a shortcut calculation using the linearity of Maxwell's equations.

Specifically, a calculation result F of a three-dimensional electromagnetic field for any one incident plane wave may be divided by an amplitude A thereof and saved as a base electromagnetic field F_{base}. For example, the calculation result F may be normalized by using the amplitude A, and the normalized calculation result may be saved as the base electromagnetic field F_{base}. When calculating the electromagnetic field for an incident wave with a different amplitude only, the solution may be B×F_{base}, which is obtained by multiplying the stored base electromagnetic field by an amplitude B thereof. Three-dimensional electromagnetic field calculations typically may use computationally expensive methods such as a finite difference time domain (FDTD) method, a rigorous coupled wave analysis (RCWA) method, a beam propagation method (BPM), and a transfer matrix method (TMM). By omitting these computationally expensive methods, the calculation speed may increase. The basis electromagnetic field to be saved is not limited to the electromagnetic field in real-space, and may be an electromagnetic field in wavevector domain or an electromagnetic field in direction cosine space. Additionally, depending on the problem, physical quantities from which three-dimensional electromagnetic fields may be derived, such as a transfer matrix, a scattering matrix, a coupling coefficient tensor, and an electromagnetic potential, may be used instead of the electromagnetic field.

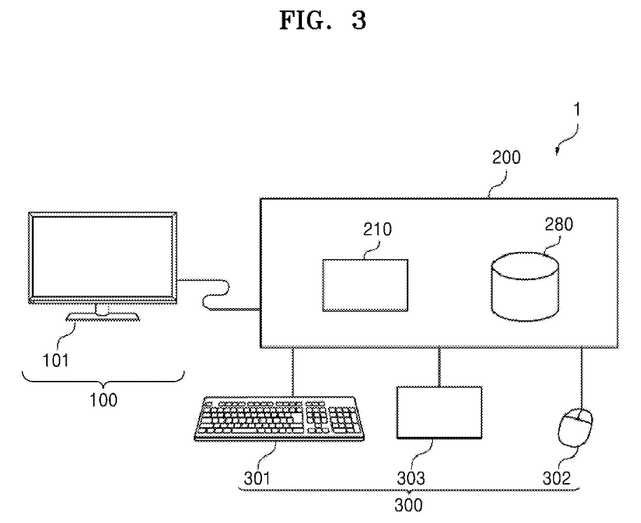

FIG. 3 is a diagram illustrating an example configuration of an electromagnetic field characteristic simulation system according to an embodiment.

The electromagnetic field characteristic simulation system 1 according to an embodiment may include a display device 100 such as a monitor 101, an input device 300 such as a keyboard 301, a mouse 302, and a tablet 303, and a computer 200 including a computing device 210 and a memory device 280, as illustrated in FIG. 3. The computer 200 may include an input unit for inputting data from the input device 300 and an output unit for outputting data to the display device 100.

The computing device 210 may include a processor such as a central processing unit (CPU) and a digital signal processor (DSP). The memory device 280 may include a memory area for storing a program for executing various data processing operations on the computing device 210 and data such as parameters and calculation results used in the data processing operations by the computing device 210. The memory area may be implemented by, for example, read only memory (ROM), random access memory (RAM), hard disk drive (HDD), flash memory, etc.

Herein, the program may include a program for electromagnetic field characteristic simulation, which causes the computer (e.g., a processor, a memory, etc.) to function as each functional unit of the electromagnetic field characteristic simulation system, and the program may be pre-installed in, for example, the memory device 280. The program may be implemented as a computer-readable recording medium, for example, a computer program product. The electromagnetic field characteristic simulation method of simulating electromagnetic field characteristics of partially coherent light incident on a three-dimensional target structure according to an embodiment may be performed by a program including one or more instructions executable by one or more processors.

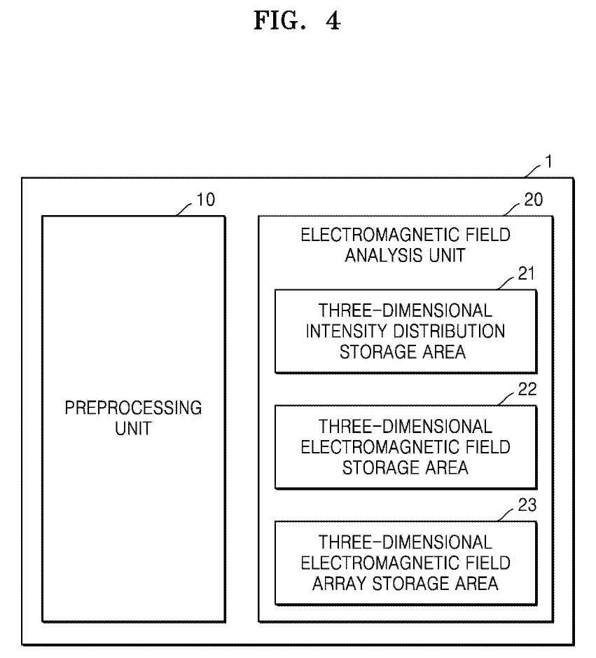

FIG. 4 is a functional block diagram illustrating an example of a computational device in an electromagnetic field characteristic simulation system, according to an embodiment.

The electromagnetic field characteristic simulation system 1 may include a preprocessing unit 10 and an electromagnetic field analysis unit 20. The electromagnetic field characteristic simulation system 1 may implement a configuration of each functional unit shown in FIG. 4 by having the processor perform various operations according to the program stored in a memory device (not shown) such as a memory, and simultaneously controlling peripheral circuits such as an analog-to-digital (A/D) conversion circuit and an input/output interface (I/F) circuit.

An electromagnetic field characteristic simulation system 1 may include the preprocessing unit 10 that decomposes partially coherent light incident on an incident surface of a three-dimensional target structure into one or more light components for each incident direction with respect to the incident surface of the three-dimensional target structure, and the electromagnetic field analysis unit 20 that analyzes the electromagnetic field for each light component.

The preprocessing unit 10 may decompose the partially coherent light incident on the three-dimensional target structure into one or more light components for each incident direction with respect to the incident surface of the three-dimensional target structure. Herein, the technique for decomposing into light components may be to extract each light component based on an incident direction using light propagation calculations.

In the preprocessing unit 10, when performing light propagation calculations, a mesh space in a wavevector domain may be defined for optical elements existing in a path from a light source to the incident surface of the three-dimensional target structure. For example, the characteristics of the optical elements such as the mask and the lens in the lithography system may guide the selection of the size and structure of a wavevector mesh of the mesh space. The mesh structure may be chosen to represent how the optical elements modulate and direct the light components.

Herein, the mesh space used in the characteristic simulation system of an embodiment will be described.

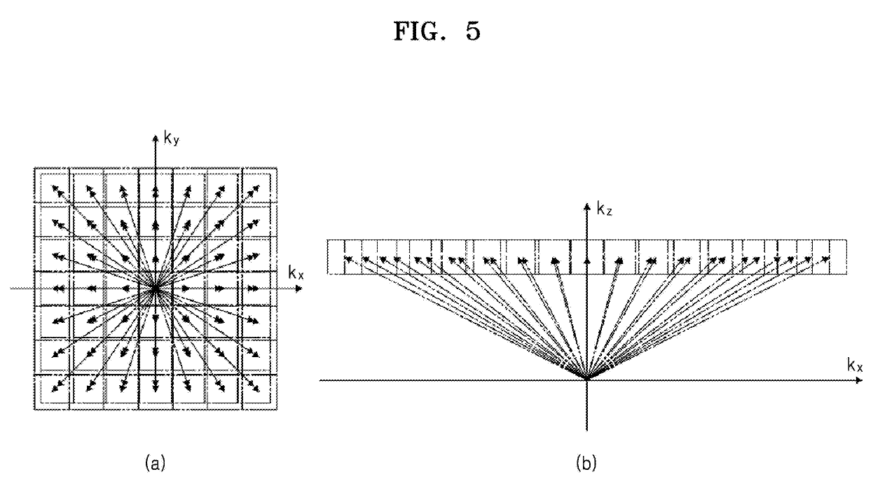

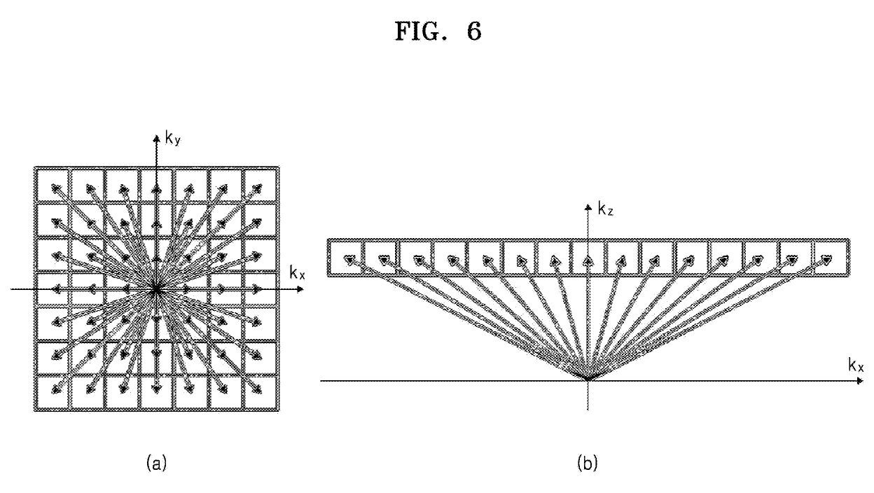

FIG. 5 is a diagram illustrating a mesh space in a wavevector domain defined for a plurality of optical elements, and FIG. 6 is a diagram illustrating a state in which a width of a mesh of the mesh space of FIG. 5 is adjusted. In each diagram, (a) is a diagram of the mesh space viewed in a plane direction, and (b) is a diagram visually depicting wave vectors corresponding to each of the mesh spaces.

In the electromagnetic field characteristic simulation system according to an embodiment, the mesh space in a wavevector domain may be defined for optical elements existing in a path from a light source to an incident surface of a three-dimensional target structure. By utilizing the mesh space, the partially coherent light incident on the three-dimensional target structure may be decomposed into one or more light components for each incident direction with respect to the incident surface of the three-dimensional target structure.

In the electromagnetic field characteristic simulation system according to an embodiment, since photolithography of the configuration shown in FIG. 1 is simulated, the mask 13 and the lens 14 may exist as optical elements existing in the path from the light source to the incident surface of the three-dimensional target structure. In this case, the mesh space corresponding to each of the mask 13 and the lens 14 may be defined. At this time, mesh widths of the two mesh spaces corresponding to the lens and the mask may be adjusted to match each other. By matching the mesh widths of the mesh spaces of the optical elements existing in the path with each other, the calculations when decomposing the light components may be simplified.

To adjust the mesh width, for example, when the mesh width of the mesh space of the mask 13 is greater than the mesh width of the mesh space of the lens 14, the mesh width of the lens 14 may be slightly narrowed so that the mesh width of the mask 13 becomes an integer multiple of the mesh width of the lens 14. For example, when the mesh width of the mask 13 is 8 and the mesh width of the lens 14 is 3, the mesh on the lens 14 may be narrowed to 2 to match the mesh width of the mask 13 by 4 times the mesh width of the lens 14. Further, by making the mesh of the mask 13 4 times finer (e.g., segmented) to align the meshes, the direction of light incident on the resist 15 may be easily aligned in the simulation. The width of the mesh may be adjusted in the direction of increasing, or in the direction of decreasing (e.g., narrowing). When adjusting in the direction of decreasing the width of the mesh, a denser mesh may more accurately represent a pupil shape of the lens 14. The same may also be applied when the mesh width relationship between the mask 13 and the lens 14 is reversed. Adjustment of the mesh width may be performed with simple calculations, as described above, so special processing such as Fourier transforms may not be required. For example, the mesh space may be defined as a grid that organizes the incident light components based on their direction of travel (i.e., a wavevector k in the wavevector space). The mesh is constructed in the wavevector domain (or k-space), not real space (like x, y, z Cartesian space). The axes represent the components of the wavevector, for example, denoted as kₓ and k_{y}, which are proportional to the angles of incidence of the light striking the target surface. Each block (a single "mesh") in this domain corresponds to a single, unique incident direction of the light component. For example, multiple light components with the same incident direction may have the same wavevector (i.e., may be mapped to the same mesh) in the wavevector domain. The mesh space is defined for the optical elements (like the mask and lens) existing in the light's path to accurately capture how the optical elements shape the light. During the decomposition process, each individual light component, which is represented as an arrow extending from the origin of the wavevector domain to a corresponding mesh, is mapped, assigned, or "decomposed into" one of these mesh blocks based on its calculated incident direction. The construction of the grid involves defining its scale and resolution. The size of the individual mesh blocks determines the resolution of the decomposition. The smaller the mesh width/size, the finer the mesh becomes (and the higher the computational resolution). For systems with multiple optical elements (like a mask and a lens), the mesh widths corresponding to each element are typically adjusted to match each other. This is done to simplify the subsequent light propagation and field analysis calculations. With the mapping of the mesh with the light component, the light components may be grouped into the same mesh that will behave identically during the subsequent complex electromagnetic field analysis.

It may be seen that the wave vectors are not aligned for the plots of each of the two mesh spaces, as the mesh widths of the mesh spaces illustrated in FIG. 5 do not match.

On the other hand, it may be seen that the wave vectors are aligned for the plots of each mesh space, as the mesh widths of the mesh spaces illustrated in FIG. 6 match to each other.

The electromagnetic field analysis unit 20 may perform electromagnetic field analysis for each light component. The electromagnetic field analysis unit 20 may analyze the electromagnetic field of each light component, which is decomposed by the preprocessing unit 10 for each incident direction relative to the incident surface of the three-dimensional target structure.

The electromagnetic field analysis unit 20 may include three storage areas of a three-dimensional intensity distribution storage area 21, a three-dimensional electromagnetic field storage area 22, and a three-dimensional electromagnetic field array storage area 23, and by storing values in these storage areas and using the values as needed during the electromagnetic field analysis calculation process, a final electromagnetic field analysis result may be obtained. The three-dimensional intensity distribution storage area 21 (also referred to as "a third storage area") may be an area for storing the intensity of the three-dimensional electromagnetic field that is finally obtained, the three-dimensional electromagnetic field storage area 22 (also referred to as "a first storage area") may be a temporary area for temporarily storing the calculation results for each light component when calculating the three-dimensional intensity distribution, and the three-dimensional electromagnetic field array storage area 23 (also referred to as "a second memory area") may be an area for storing the electromagnetic field analysis results for each unit component for each incident direction.

The electromagnetic field analysis unit 20 may analyze the electromagnetic field for each light component of each plot of the mesh space when defining the mesh space in the preprocessing unit 10. The electromagnetic field analysis unit 20 may determine whether the light component in each plot is the light component for which electromagnetic field analysis is first calculated in the plot, and adopt a different calculation technique depending on the result of the determination. For example, when three light components are associated with or mapped to the same mesh, the electromagnetic field analysis unit 20 may determine whether electromagnetic field analysis is performed on the mesh for the first time. If it is determined that the analysis is performed on the mesh (i.e., the incidence direction) for the first time, the electromagnetic field analysis unit 20 may perform a full calculation using electromagnetic field analysis such as FDTD and RCWA. If it is determined that the analysis is already performed on the mesh, a shortcut calculation is performed to avoid the full calculation. For example, in the shortcut calculation, the stored normalized result F_{base} (i.e., the base electromagnetic field) is retrieved, and then the amplitude of the current light component assigned on the same mesh is multiplied to the normalized result F_{base} to obtain a result of the electromagnetic field analysis without performing the full calculation.

The electromagnetic field analysis unit 20 may perform electromagnetic field analysis calculations using a technique that numerically analyzes Maxwell’s equations for only the light component that is first calculated in the electromagnetic field analysis. The electromagnetic field analysis unit 20 may store the result of the electromagnetic field analysis calculations in the second storage area, which is initially calculated in an incident direction thereof, and store the normalized result obtained by the result of the electromagnetic field analysis calculation being divided by the amplitude of the light component may be stored in the second storage area, linking the normalized result to the incident direction of the light component. For example, the address of the second storage may be mapped to a corresponding mesh which represent the incident direction of the light component.

For light components that are not initially subjected to the electromagnetic field analysis calculations in the incident direction thereof, the electromagnetic field analysis unit 20 may multiply the electromagnetic field analysis result of the unit component in the same incident direction, among those stored in the second storage area, by the amplitude of the light component thereof to be calculated, and store this value in the second storage area, instead of the value calculated in the electromagnetic field analysis calculations performed using a technique for numerically analyzing Maxwell's equations.

When the electromagnetic field analysis unit 20 performs electromagnetic field analysis calculations (i.e., full calculations) or alternative calculations (i.e., shortcut calculations) for all light components, the electromagnetic field analysis unit 20 may add the square of the absolute value of the value stored in the first storage area and store the result thereof in the third storage area. The electromagnetic field analysis unit 20 may simulate electromagnetic field characteristics by outputting the values stored in the third storage area as three-dimensional intensity distribution data.

Next, an electromagnetic field characteristic simulation method executed in an electromagnetic field characteristic simulation system according to an embodiment will be described.

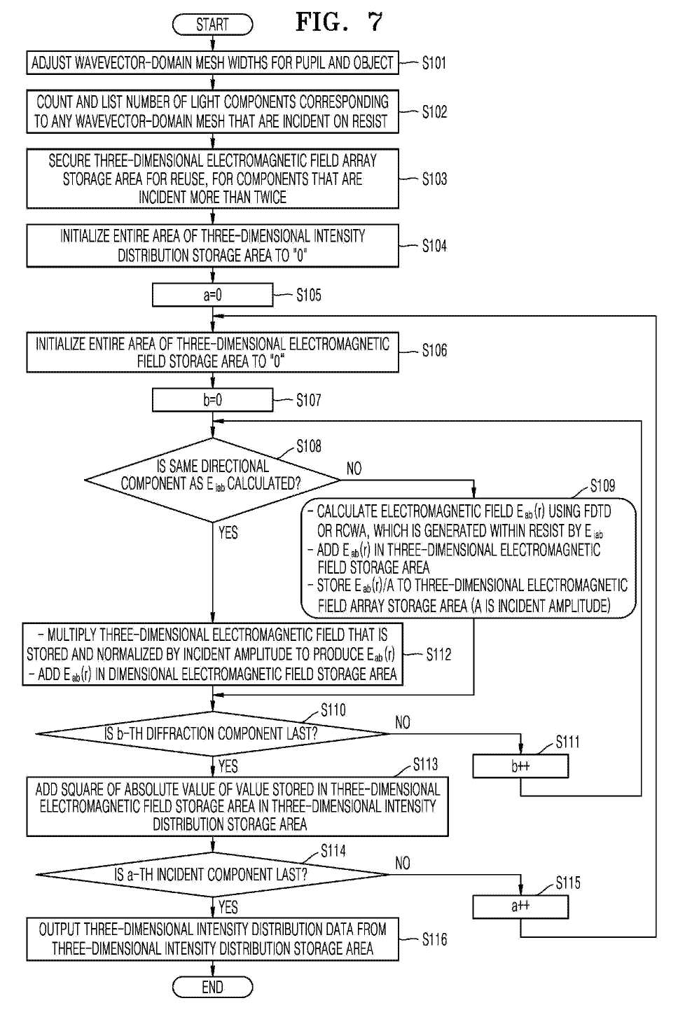

FIG. 7 is a diagram illustrating an example of processing flow of an electromagnetic field characteristic simulation method.

The electromagnetic field characteristic simulation system 1 according to an embodiment may be realized by the computing device 210 and the memory device 280 of the computer 200 executing each process from operation S101 to operation S116 of FIG. 7 according to a program. Operations S101 to S102 may be executed by the preprocessing unit 10, and operations S103 to S116 may be executed by the electromagnetic field analysis unit 20.

First, in the electromagnetic field characteristic simulation system 1, the preprocessing unit 10 may generate a mesh space in a wavevector domain and adjust wavevector-domain mesh widths for a pupil (e.g., the lens 14) and an object (e.g., the mask 13) (operation S101), and then count and list the number of light components corresponding to each wavevector-domain mesh (operation S102). The light components are incident on the resist 15.

In the electromagnetic field characteristic simulation system 1, the electromagnetic field analysis unit 20 may execute processing from operation S103 to operation S116 after operation S102. First, a storage area may be set in operation S102. The three-dimensional electromagnetic field array storage area 23 (e.g., the second storage area) for reuse of the full calculation result may be secured for light components that are incident more than twice in the same incident direction on the surface of the resist 15 (operation S103), and the three-dimensional intensity distribution storage area 21 (e.g., the third storage area) that stores the intensity of the electromagnetic field generated within the resist 15 by all incident light components may be initialized to "0" throughout the entire area (operation S104).

Next, a component "a" of the light source may be reset to "0" (operation S105), and the three-dimensional electromagnetic field storage area 22 (e.g., the first storage area), which stores the calculation result of the electromagnetic field generated within the resist 15 by the a-th incident light, may be initialized to "0" throughout the entire area (operation S106). For example, as shown in FIG. 1, the light source 11 may be modeled as having three incident lights. The incident light, shown as the component (a) of FIG. 1, may be indexed as a first incident light. The incident light, shown as the component (b) of FIG. 1, may be indexed as a second incident light. The incident light, shown as the component (c) of FIG. 1, may be indexed as a third incident light.

After operation S106, a component "b" for each diffraction may be reset to "0" (operation S107), and it may be determined whether the same directional component as the light components E_{iab} for which electromagnetic field analysis calculation is attempted has already been calculated (operation S108). For example, as shown in FIG. 1, the mask 12 may diffract an incident light, and such diffracted light is delivered to the resist 15 through the lens 14. In an embodiment, each diffracted light may be modeled as a light component of the a-th incident light of the light source. For example, in component (a) of FIG. 1, the mask 13 may diffract the first incident light emitted from the light source 11 into three light components of the first incident light, which will be incident on the resist 15 via the lens. In this case, the three diffracted light components may be indexed as b=1, b=2, and b=3, respectively. This description applies to the second incident light and the third incident light.

In operation S108, when it is determined that the same directional component has not already been calculated (operation S108: NO), the electromagnetic field E_{ab} generated within the resist 15 by the light components E_{iab} for which the electromagnetic field analysis is to be calculated may be calculated using FDTD technique or RCWA technique (e.g., using full calculation), and the E_{ab}(r) calculated in this way may be added to the three-dimensional electromagnetic field storage area 22 (e.g., the first storage area), and a value E_{ab}(r)/A (e.g., a normalized value by the amplitude A or basis electromagnetic field), which is obtained by dividing the calculated E_{ab}(r) by the amplitude A of the light component E_{iab}, may be stored in the three-dimensional electromagnetic field array storage area 23 (e.g., the second storage area) (operation S109). In addition, the FDTD and RCWA techniques are examples of techniques for calculating electromagnetic field analysis using a method of numerically analyzing the Maxwell's equations, but are not limited thereto.

In operation S108, when it is determined that the same directional component has already been calculated (operation S108: YES), the normalized value already stored for the same incident direction may be multiplied by an incident amplitude of the light components E_{iab} for which the electromagnetic field analysis calculation is to be performed, and the resulting value may be calculated as the electromagnetic field E_{ab} to be generated within the resist 15. The calculated value, E_{ab}(r) calculated in this way may be added to the three-dimensional electromagnetic field storage area 22 (e.g., the first storage area) (operation S112). In an embodiment, when a value stored at an address corresponding to an incident direction is greater than zero, it is determined that the full calculation has been performed on the incident direction.

After operation S109 or operation S112 is performed, it may be determined whether all diffraction components have been calculated for the same incident direction (operation S110). When this is not the last diffraction component (when all diffraction components have not been calculated) (operation S110: NO), the next diffraction component may be set as the light component E_{iab} for which the electromagnetic field analysis calculation is to be performed (operation S111), and the process may return to operation S108 to repeat the processing of the electromagnetic field analysis calculation for the next diffraction component.

In operation S110, when it is determined that all diffraction components have been calculated (operation S110: YES), the square of the absolute value of the value stored in the three-dimensional electromagnetic field storage area 22 (e.g., the first storage area) may be added to the three-dimensional intensity distribution storage area 21 (e.g., the third storage area) (operation S113). Afterwards, it may be determined whether the calculation of electromagnetic field analysis for all incident direction components has been completed (operation S114). For example, in operation S114, it may be determined that the calculation of electromagnetic field analysis for the three incident directions as shown in FIG. 1 has been completed.

In operation S114, when it is determined that the calculation of the electromagnetic field analysis for all incident direction components has not been completed (operation S114: NO), the process may return to operation S106 and repeat the processing of the electromagnetic field analysis calculation for the light component of the next incident direction.

In operation S114, when it is determined that the calculation of electromagnetic field analysis for all incident direction components has been completed (operation S114: YES), three-dimensional intensity distribution data may be output from the three-dimensional intensity distribution storage area 21 (operation S116).

Here, in order to verify the effectiveness of the electromagnetic field characteristic simulation method according to an embodiment, an electromagnetic field characteristic simulation according to a comparative example was performed and the calculation time therebetween was compared.

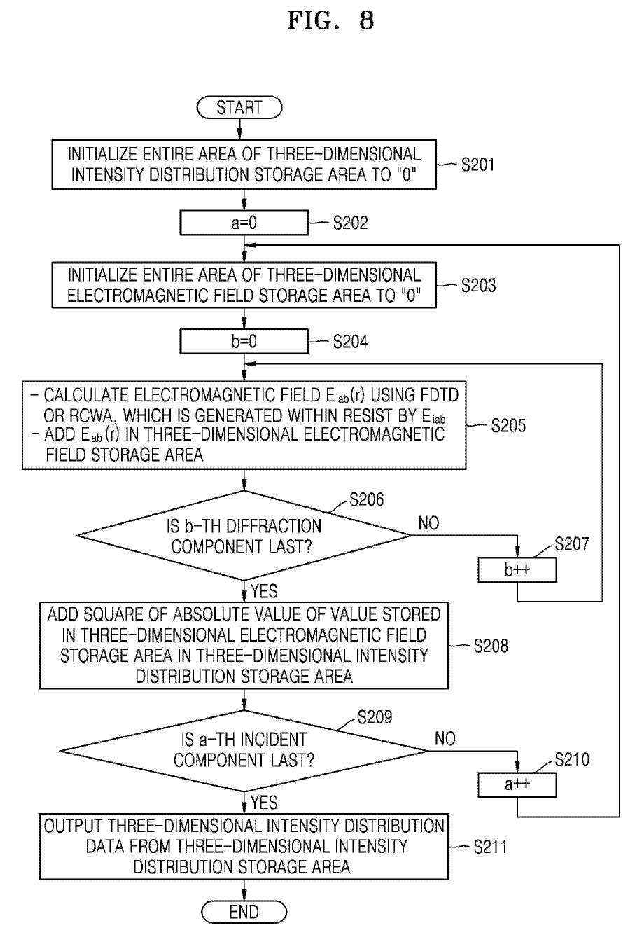

FIG. 8 is a diagram illustrating an example of processing flow of an electromagnetic field characteristic simulation method, according to a comparative example.

According to the comparative example, since the calculation method thereof is not changed for components that are incident more than twice in the same incident direction on the surface of the resist 15, the three-dimensional electromagnetic field array storage area 23 (e.g., the second storage area) for reuse is unnecessary. In addition, operations S101 to S102 executed by the preprocessing unit 10 of an embodiment are unnecessary.

In the electromagnetic field characteristic simulation method according to the comparative example, first, the three-dimensional intensity distribution storage area 21 (e.g., the third storage area), which stores the intensity of the electromagnetic field generated within the resist 15 by all components of incident light, is initialized to "0" throughout the entire area thereof (operation S201).

Next, a component "a" of the light source is reset to "0" (operation S202), and the three-dimensional electromagnetic field storage area 22 (e.g., the first storage area), which stores the calculation result of the electromagnetic field generated within the resist 15 by the a-th incident light, is initialized to "0" throughout the entire area (operation S203).

After operation S203, a component "b" for each diffraction is reset to "0" (operation S204), and the electromagnetic field E_{ab} generated within the resist 15 by the light component E_{iab} for which the electromagnetic field analysis calculation is to be performed is calculated using FDTD technique or RCWA technique, and the calculated E_{ab}(r) is added to the three-dimensional electromagnetic field storage area 22 (e.g., the first storage area) (operation S205).

After operation S205, it is determined whether all diffraction components have been calculated for the same incident direction (operation S206). When this is not the last diffraction component (when all diffraction components have not been calculated) (operation S206: NO), the next diffraction component is set as the light component E_{iab} for which the electromagnetic field analysis calculation is to be performed (operation S207), and the process may return to operation S205 to repeat the processing of the electromagnetic field analysis calculation for the next diffraction component.

In operation S206, when it is determined that all diffraction components have been calculated (operation S206: YES), the square of the absolute value of the value stored in the three-dimensional electromagnetic field storage area 22 (e.g., the first storage area) is added to the three-dimensional intensity distribution storage area 21 (e.g., the third storage area) (operation S208). Afterwards, it may be determined whether the calculation of electromagnetic field analysis for all incident direction components has been completed (operation S209).

In operation S209, when it is determined that the calculation of the electromagnetic field analysis for all incident direction components has not been completed (operation S209: NO), the process returns to operation S203 and repeat the processing of the electromagnetic field analysis calculation for the light component of the next incident direction.

In operation S209, when it is determined that the calculation of electromagnetic field analysis for all incident direction components has been completed (operation S209: YES), three-dimensional intensity distribution data is output from the three-dimensional intensity distribution storage area 21 (operation S211).

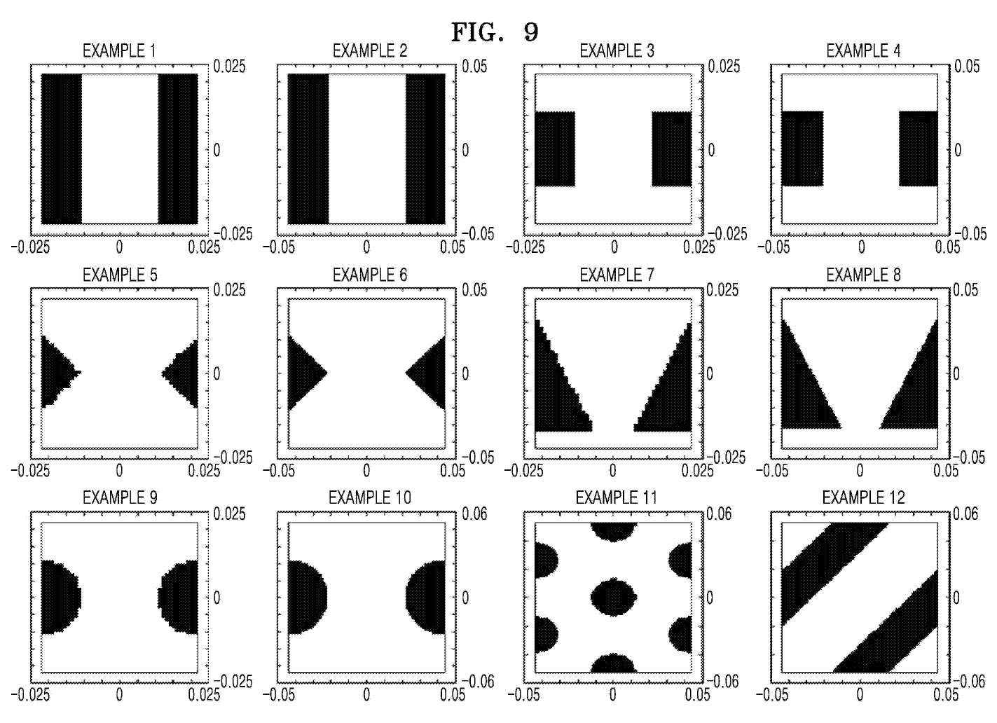

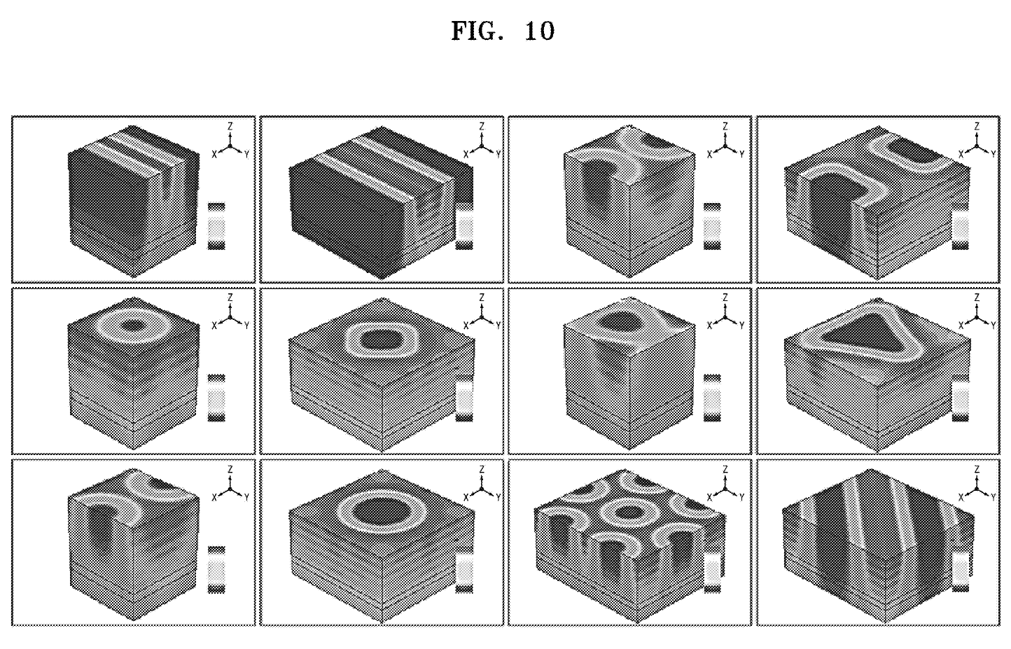

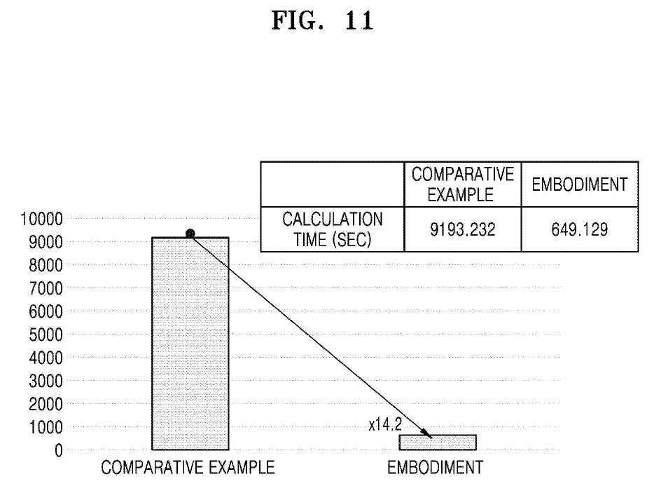

FIG. 9 is a diagram illustrating shapes of masks used as an example in the simulation of electromagnetic field characteristics in photolithography. FIG. 10 is a diagram illustrating electromagnetic field characteristics simulated when the masks of FIG. 9 are used. FIG. 11 is a diagram illustrating the calculation time when an electromagnetic field characteristic simulation method according to an embodiment and an electromagnetic field characteristic simulation method according to a comparative example are executed.

In order to verify the effectiveness of the electromagnetic field characteristic simulation method of an embodiment, electromagnetic field characteristic simulations were performed through the processing technique of FIG. 7 using masks shown in Examples 1 to 12 of FIG. 9 as the mask 13 for photolithography, and the simulation results shown in FIG. 10 were obtained.

Likewise, electromagnetic field characteristic simulations were performed through the processing technique according to the comparative example shown in FIG. 8 using masks shown in Examples 1 to 12 of FIG. 9 as the mask 13 for photolithography, and the simulation results shown in FIG. 10 were obtained.

From these results, it may be seen that the electromagnetic field characteristic simulation method of an embodiment may obtain the same simulation results as the electromagnetic field characteristic simulation method according to the comparative example.

On the other hand, as illustrated in FIG. 11, it may be seen that the calculation time required by the electromagnetic field characteristic simulation method of an embodiment may be shortened by 1/14.2 of the calculation time required by the electromagnetic field characteristic simulation method of the comparative example.

Therefore, it may be seen that the electromagnetic field characteristic simulation method of an embodiment may obtain the same simulation result with a shorter calculation time than the electromagnetic field characteristic simulation method according to the comparative example.

The electromagnetic field characteristic simulation method according to an embodiment of the disclosure has been specifically described based on embodiments, but the disclosure is not limited thereto and may be variously modified without departing from the scope of the disclosure.

In the electromagnetic field characteristic simulation system of an embodiment, the case of realizing electromagnetic field characteristic simulation in photolithography is described as an example, but it may be used in cases of realizing electromagnetic field characteristic simulation in various processes when it is optical propagation using partially coherent light.

The configuration of the electromagnetic field characteristic simulation system of an embodiment is not limited to the configurations of FIGS. 3 and 4. For example, in the embodiment, the computing device 210 is described as an example of performing processing based on data stored in the memory device 280, but the disclosure is not limited thereto. The computing device 210 may perform processing based on data received from an external data source via a network. The network’s communication form is not limited to wireless and may be configured as a wired connection. In that case, a router for Ethernet connection may be used instead of a wireless local area network (LAN) base station.

In the above embodiment, it is not determined whether the incident direction is symmetrical with respect to the incident surface or not. In an embodiment, an additional calculation shortcut may be employed. For example, when a first light component (i.e., a subsequent light component) has an incident direction with respect to the incident surface that is different from, but symmetric to, a second light component (i.e., a current light component) for which a full calculation has already been performed, the electromagnetic field analysis result for the first light component may be obtained without performing a full calculation. For example, in the case where it is determined as NO in operation S108 of FIG. 7, it may be determined whether the incident direction is symmetrical with respect to the incident surface or not. In a case where the electromagnetic field analysis calculation result of the light components that are symmetrical with respect to the incident surface is already stored in the second storage area, the stored electromagnetic field analysis calculation result may be inverted and multiplied by the amplitude of the light component to be calculated, and the result may be obtained as the electromagnetic field analysis calculation.

In the above embodiment, in FIG. 7, it is determined whether the light component with the same direction as the light component being calculated has already been calculated (operation S108), and when the light component has already been calculated, instead of performing the electromagnetic field analysis calculation using a method that numerically analyzes Maxwell's equations, a process of multiplying the result of the normalized electromagnetic field analysis calculation by the amplitude thereof may be performed (operation S112), but this is not limited thereto. Operation S108 and operation S112 may be optionally omitted. When omitted, storing the result in the second storage area in operation S109 may be unnecessary. When the processing of operations S108 and S112 is omitted, the third storage area is not required, and therefore memory resources may be saved. Therefore, by selectively executing the processing of operations S108 and S112, it may be possible to select whether to shorten the calculation time (when executing the processing of operations S108 and S112) or to save the memory resources (when omitting the processing of operations S108 and S112).

According to an embodiment, an electromagnetic field characteristic simulation method in which a computer uses an electromagnetic field analysis technique to simulate electromagnetic field characteristics of partially coherent light incident on a three-dimensional target structure may include operations of decomposing the partially coherent light incident on an incident surface of the three-dimensional target structure into one or more light components for each incident direction with respect to the incident surface of the three-dimensional target structure, and performing an electromagnetic field analysis on each of the light components, wherein the performing of an electromagnetic field analysis may repeat the operations of determining whether or not the light component is a light component that is firstly calculated by an electromagnetic field analysis calculation among the light components with the same incident direction with respect to the incident surface, obtaining a result of the electromagnetic field analysis calculation by executing an operation according to a result of the determining, adding the result of the electromagnetic field analysis calculation obtained in the obtaining to an accumulated result, and storing the accumulated result in a first storage area, and normalizing the result of the electromagnetic field analysis calculation with respect to the light component that is firstly calculated among the light components with the same incident direction with respect to the incident surface, connecting a normalized result to the incident direction with respect to the incident surface of the light components, and storing the normalized result in a second storage area. The obtaining a result of the electromagnetic field analysis calculation may include operations of obtaining the result of the electromagnetic field analysis calculation by executing the operation of the electromagnetic field analysis calculation by using a technique that numerically analyzes Maxwell's equations, for a first light component that is determined to be the light component that is firstly calculated by the electromagnetic field analysis calculation among the light components with the same incident direction with respect to the incident surface, and obtaining a result obtained by executing an operation that multiplies the amplitude of a second light component by the normalized result of the electromagnetic field analysis calculation stored in the second storage area, as the result of the electromagnetic field analysis calculation, for the second light component that is determined not to be the light component that is firstly calculated by the electromagnetic field analysis calculation among the light components with the same incident direction with respect to the incident surface.

In some embodiments, in the decomposing of the partially coherent light into light components, when calculating the light components of the partially coherent light incident on the three-dimensional target structure, a mesh space in wavevector domain may be defined for optical elements existing in a path from a light source of the partially coherent light to the incident surface of the three-dimensional target structure, and the light components of the partially coherent light incident on the three-dimensional target structure may be decomposed into the mesh space in the wavevector domain.

In some embodiments, in the decomposing of the partially coherent light into light components, the light components incident on a same mesh of the mesh space may be extracted in advance, and in the storing, when there are multiple light components incident on the same mesh, the storing may be performed in the second storage area.

In some embodiments, in the obtaining of the result of the electromagnetic field analysis calculation, for light components with the incident direction symmetrical with respect to the incident surface, when a result of the electromagnetic field analysis calculation of a second light component paired with a first light component to be obtained is stored as a first result in the second storage area, the first result may be inverted and a value obtained by multiplying an inverted first result by the amplitude of the first light component may be obtained as the result of the electromagnetic field analysis calculation.

In some embodiments, the electromagnetic field analysis calculation may be performed using any one of physical quantities including a transmission matrix, a scattering matrix, a coupling coefficient tensor, and an electron potential, which may derive a three-dimensional electromagnetic field, instead of calculating the electromagnetic field as it is.

In some embodiments, the obtaining of the result of the electromagnetic field analysis calculation may further comprise selecting whether to omit the determining before executing the determining, and when it is selected to omit the determining in the selecting, in the obtaining of the result of the electromagnetic field analysis calculation, an operation of the electromagnetic field analysis calculation by using a technique that numerically analyzes Maxwell's equations for all light components may be executed to obtain the result of the electromagnetic field analysis calculation, and the storing the result in the second storage area may not be executed.

An electromagnetic field characteristic simulation program according to an embodiment may be a program for executing each operation of an electromagnetic field characteristic simulation method among the aforementioned methods on a computer, and may be stored in a computer-readable recording medium.

According to an embodiment, an electromagnetic field characteristic simulation system may include a computing device and a memory device and simulating electromagnetic field characteristics of partially coherent light incident on a three-dimensional target structure using an electromagnetic field analysis technique, wherein the memory device may store a program in the computing device, that may cause the computing device to execute the operations of decomposing the partially coherent light incident on an incident surface of the three-dimensional target structure into one or more light components for each incident direction with respect to the incident surface of the three-dimensional target structure, and performing an electromagnetic field analysis on each of the light components, wherein the performing of an electromagnetic field analysis may repeat the operations of determining whether or not the light component is a light component that is firstly calculated by an electromagnetic field analysis calculation among the light components with the same incident direction with respect to the incident surface, obtaining a result of the electromagnetic field analysis calculation by executing an operation according to a result of the determining, adding the result of the electromagnetic field analysis calculation obtained in the obtaining to a accumulated result, and storing the accumulated result in a first storage area, and normalizing the result of the electromagnetic field analysis calculation with respect to the light component to be firstly calculated among the light components with the same incident direction with respect to the incident surface, connecting a normalized result to the incident direction with respect to the incident surface of the light components, and storing the normalized result in a second storage area. In the obtaining of the result of the electromagnetic field analysis calculation, for a light component that is determined to be the light component that is firstly calculated by the electromagnetic field analysis calculation among the light components with the same incident direction with respect to the incident surface, the result of the electromagnetic field analysis calculation by executing the operation of the electromagnetic field analysis calculation by using a technique that numerically analyzes Maxwell's equations may be obtained, and for a light component that is determined not to be the light component that is firstly calculated by the electromagnetic field analysis calculation among the light components with the same incident direction with respect to the incident surface, the result obtained by executing an operation that multiplies the normalized result of the electromagnetic field analysis calculation stored in the second storage area by the amplitude of the second light component may be obtained, as the result of the electromagnetic field analysis calculation.

According to an embodiment, an electromagnetic field characteristic simulation system may include a processor and a memory that stores instructions executed by the processor, wherein by executing the instructions, the processor may decompose partially coherent light incident on an incident surface of a resist into one or more light components for each incident direction with respect to the incident surface, perform an operation of an electromagnetic field analysis calculation to produce a first calculation result, for a first light component that is firstly calculated by the electromagnetic field analysis calculation among the light components with the same incident direction with respect to the incident surface, normalize the first calculation result to generate a normalized result, and perform an operation of multiplying the normalized result by the amplitude of a second light component to produce a second calculation result, in which the second light component is not a light component that is firstly calculated by the electromagnetic field analysis calculation among the light components with the same incident direction with respect to the incident surface.

While the disclosure has been particularly shown and described with reference to embodiments thereof, it will be understood that various changes in form and details may be made therein without departing from the spirit and scope of the following claims.

What is claimed is:

1. An electromagnetic field characteristic simulation method, in which a computer uses an electromagnetic field analysis technique to simulate electromagnetic field characteristics of partially coherent light incident on a three-dimensional target structure, the method comprising:
decomposing the partially coherent light incident on an incident surface of the three-dimensional target structure into one or more light components for each incident direction with respect to the incident surface of the three-dimensional target structure; and
performing an electromagnetic field analysis on each of the one or more light components,
wherein the performing of the electromagnetic field analysis repeats operations of:
determining whether or not a current light component on which the electromagnetic field analysis is to be performed is a light component that is firstly calculated by an electromagnetic field analysis calculation among one or more light components with a same incident direction with respect to the incident surface, wherein the one or more light components with the same incident direction includes the current light component;
obtaining a result of the electromagnetic field analysis calculation by executing an operation on the current light component according to a result of the determining;
adding the result of the electromagnetic field analysis calculation obtained in the obtaining to an accumulated result, and storing the accumulated result in a first storage area; and
normalizing the result of the electromagnetic field analysis calculation in response to the current light component being determined as the light component that is firstly calculated among the one or more light components with the same incident direction with respect to the incident surface, associating the normalized result to the same incident direction with respect to the incident surface, and storing the normalized result in a second storage area.

2. The electromagnetic field characteristic simulation method of claim 1,
wherein the obtaining of the result of the electromagnetic field analysis calculation comprises:
obtaining the result of the electromagnetic field analysis calculation by executing the operation of the electromagnetic field analysis calculation by using a technique that numerically analyzes Maxwell's equations, for the current light component being a first light component that is determined to be the light component that is firstly calculated by the electromagnetic field analysis calculation among the one or more light components with the same incident direction with respect to the incident surface; and
obtaining a result obtained by multiplying an amplitude of a second light component by the normalized result stored in the second storage area for the current light component being the second light component that is determined not to be the light component that is firstly calculated by the electromagnetic field analysis calculation among the one or more light components with the same incident direction with respect to the incident surface.

3. The electromagnetic field characteristic simulation method of claim 1,
wherein in the decomposing of the partially coherent light into the one or more light components, a mesh space in a wavevector domain is defined for optical elements existing in a path from a light source of the partially coherent light to the incident surface of the three-dimensional target structure, and the one or more light components of the partially coherent light incident on the three-dimensional target structure are decomposed into the mesh space in the wavevector domain.

4. The electromagnetic field characteristic simulation method of claim 3,
wherein in the decomposing of the partially coherent light into light components, the one or more light components with the same incident direction are extracted,
wherein the one or more light components with the same incident direction correspond to the same mesh of the mesh space in the wavevector domain, and
wherein the storing of the normalized result in the second storage area is performed when multiple light components have the same wavevector.

5. The electromagnetic field characteristic simulation method of claim 1,
wherein in the obtaining of the result of the electromagnetic field analysis calculation, when a subsequent light component has an incident direction with respect to the incident surface symmetrical to an incident direction of the current light component, the result of the current light component is inverted, and a value obtained by multiplying the inverted result by an amplitude of the subsequent light component is obtained as the result of the electromagnetic field analysis calculation of the another light component.

6. The electromagnetic field characteristic simulation method of claim 1,
wherein the electromagnetic field analysis calculation is performed using any one of physical quantities including a transmission matrix, a scattering matrix, a coupling coefficient tensor, and an electron potential, which derive a three-dimensional electromagnetic field.

7. The electromagnetic field characteristic simulation method of claim 1,
wherein the obtaining of the result of the electromagnetic field analysis calculation further comprises:
selecting whether to omit the determining before executing the determining, and
wherein when it is selected to omit the determining in the selecting, in the obtaining of the result of the electromagnetic field analysis calculation, an operation of the electromagnetic field analysis calculation by using a technique that numerically analyzes Maxwell's equations for all light components is executed to obtain the result of the electromagnetic field analysis calculation, and the storing the result in the second storage area is not executed.

8. A computer-readable recording medium comprising a program for causing a computer to execute each operation of the electromagnetic field characteristic simulation method of claim 1.

9. An electromagnetic field characteristic simulation system comprising a computing device and a memory device, and simulating electromagnetic field characteristics of partially coherent light incident on a three-dimensional target structure using an electromagnetic field analysis technique, wherein the memory device stores a program to be run in the computing device, the program causes the computing device to execute operations of:
decomposing the partially coherent light incident on an incident surface of the three-dimensional target structure into one or more light components for each incident direction with respect to the incident surface of the three-dimensional target structure; and
performing an electromagnetic field analysis on each of the one or more light components,
wherein the performing of the electromagnetic field analysis repeats operations of:
determining whether or not a current light component on which the electromagnetic field analysis is to be performed is a light component that is firstly calculated by an electromagnetic field analysis calculation among one or more light components with a same incident direction with respect to the incident surface, wherein the one or more light components with the same incident direction includes the current light component;
obtaining a result of the electromagnetic field analysis calculation by executing an operation on the current light component according to a result of the determining;
adding the result of the electromagnetic field analysis calculation obtained in the obtaining, and storing the result in a first storage area; and
normalizing the result of the electromagnetic field analysis calculation in response to the current light component being determined as the light component to be firstly calculated among the one or more light components with the same incident direction with respect to the incident surface, associating the normalized result to the incident direction with respect to the incident surface, and storing the normalized result in a second storage area.

10. The electromagnetic field characteristic simulation system of claim 9,
wherein in the obtaining of the result of the electromagnetic field analysis calculation,
for the current light component that is determined to be the light component that is firstly calculated by the electromagnetic field analysis calculation among the one or more light components with the same incident direction with respect to the incident surface, the result of the electromagnetic field analysis calculation by executing the operation of the electromagnetic field analysis calculation by using a technique that numerically analyzes Maxwell's equations is obtained; and
for the current light component that is determined not to be the light component that is firstly calculated by the electromagnetic field analysis calculation among the one or more light components with the same incident direction with respect to the incident surface, a result of multiplying the normalized result of the electromagnetic field analysis calculation stored in the second storage area by an amplitude of the current light component that is determined not to be the light component that is firstly calculated by the electromagnetic field analysis calculation is obtained, as the result of the electromagnetic field analysis calculation.

11. The electromagnetic field characteristic simulation system of claim 9,
wherein in the decomposing of the partially coherent light into the one or more light components, a mesh space in a wavevector domain is defined for optical elements existing in a path from a light source of the partially coherent light to the incident surface of the three-dimensional target structure, and the one or more light components of the partially coherent light incident on the three-dimensional target structure are decomposed into the mesh space in the wavevector domain.

12. The electromagnetic field characteristic simulation system of claim 11,
wherein in the decomposing of the partially coherent light into light components, the one or more light components with the same incident direction are extracted,
wherein the one or more light components with the same incident direction correspond to the same mesh of the mesh space in the wavevector domain, and
wherein the storing of the normalized result in the second storage area is performed when multiple light components have the same wavevector.

13. The electromagnetic field characteristic simulation system of claim 9,
wherein in the obtaining of the result of the electromagnetic field analysis calculation, when a subsequent light component has an incident direction with respect to the incident surface symmetrical to an incident direction of the current light component, the result of the current light component is inverted, and a value obtained by multiplying the inverted result by an amplitude of the subsequent light component is obtained as the result of the electromagnetic field analysis calculation of the another light component.

14. The electromagnetic field characteristic simulation system of claim 9,
wherein the electromagnetic field analysis calculation is performed using any one of physical quantities including a transmission matrix, a scattering matrix, a coupling coefficient tensor, and an electron potential, which derive a three-dimensional electromagnetic field.

15. The electromagnetic field characteristic simulation system of claim 9,
wherein the obtaining of the result of the electromagnetic field analysis calculation further comprises selecting whether to omit the determining before executing the determining, and when it is selected to omit the determining in the selecting, in the obtaining of the result of the electromagnetic field analysis calculation, an operation of the electromagnetic field analysis calculation by using a technique that numerically analyzes Maxwell's equations for all light components is executed to obtain the result of the electromagnetic field analysis calculation, and the storing the result in the second storage area is not executed.

16. An electromagnetic field characteristic simulation system, comprising:
a processor; and
a memory that stores instructions executed by the processor,
wherein the processor is configured to, by executing the instructions:
decompose partially coherent light incident on an incident surface of a resist into one or more light components for each incident direction with respect to the incident surface;
perform an operation of an electromagnetic field analysis calculation to produce a first calculation result, for a first light component that is firstly calculated by the electromagnetic field analysis calculation among one or more light components with a same incident direction with respect to the incident surface;
normalize the first calculation result to generate a normalized result; and
perform an operation of multiplying the normalized result by an amplitude of a second light component to produce a second calculation result, in which the second light component is not a light component that is firstly calculated by the electromagnetic field analysis calculation among the one or more light components with the same incident direction with respect to the incident surface.

17. The electromagnetic field characteristic simulation system of claim 16,
wherein the processor is further configured to, by executing the instructions, execute the electromagnetic field analysis calculation using a technique that numerically analyzes Maxwell's equations for the first light component to produce the first calculation result.

18. The electromagnetic field characteristic simulation system of claim 16,
wherein the processor is further configured to, by executing the instructions, obtain a third calculation result by performing an operation of multiplying an inverted result of the normalized result by the amplitude of a third light component that has an incident direction symmetrical to the first light component with respect to the incident surface.

19. The electromagnetic field characteristic simulation system of claim 16,
wherein the processor is further configured to, by executing the instructions:
define a mesh space in wavevector domain for one or more optical elements existing in a path from a light source of the partially coherent light to the incident surface;
decompose the light components of the partially coherent light into the mesh space in the wavevector domain; and
extract the one or more light components with the same incident direction, and
wherein the one or more light components with the same incident direction correspond to the same mesh of the mesh space in the wavevector domain.

20. The electromagnetic field characteristic simulation system of claim 16,
wherein the processor is further configured to, by executing the instructions:
define a mesh space in wavevector domain for each mask and lens existing in a path from a light source of the partially coherent light to the incident surface; and
adjust a mesh width of a first mesh space for the mask to be an integer multiple of a mesh width of a second mesh space for the lens.
